(19) United States
(12) Patent Application Publication
(10) Pub. No.: US 2016/0007478 A1
(43) Pub. Date: Jan. 7, 2016

(54) DISPLAY DEVICE

(71) Applicant: Au Optronics Corporation, Hsinchu (TW)

(72) Inventors: Ching-Kun Lai, Changhua County (TW); Chun-Chi Chi, Taichung City (TW); Kai-Tzu Cheng, Hsinchu County (TW)

(21) Appl. No.: 14/533,095

(22) Filed: Nov. 5, 2014

(30) Foreign Application Priority Data
Jul. 1, 2014 (TW) 103122676

(51) Int. Cl. H05K 3/28; H05K 1/03

(52) U.S. Cl. CPC H05K 3/28; H05K 1/0393; H05K 2201/10128; H05K 2203/1173

(57) ABSTRACT

A display device includes a first substrate, at least one trace, a hydrophobic protective layer, a flexible printed circuit board (FPCB), a second substrate and a sealant. The first substrate has a display region and a peripheral region having an outer lead bonding (OLB) portion. The trace and the hydrophobic protective layer are disposed on the first substrate and extend from the display region to the OLB portion. The hydrophobic protective layer covers the trace and has at least one opening exposing a portion of the trace to define at least one lead and a surface microstructure. The lead and the surface microstructure are located in the OLB portion, and the surface microstructure is located on a surface of the hydrophobic protective layer away from the trace. One end of the FPCB leans against the surface microstructure and the FPCB is electrically connected to the lead.

### CROSS-REFERENCE TO RELATED APPLICATION

This application claims the priority benefit of Taiwan application serial no. 103122676, filed on Jul. 1, 2014. The entirety of the above-mentioned patent application is hereby incorporated by reference herein and made a part of this specification.

### BACKGROUND OF THE INVENTION

1. Field of the Invention

The present invention generally relates to a display device, and more particularly, to a display device having favorable structure structural reliability.

2. Description of Related Art

In general, conventional display device is usually configured with a protective glue (such as Tiffy glue) in an out lead bonding region of a peripheral region for protecting leads of peripheral circuit and strengthening the protection of signal traces. However, the protective glue has a rework characteristic, and thereby an adhesion thereof is relatively weak. In addition, a cleaning liquid for cleaning the display device is apt to infiltrate from a seam between the protective glue and the out lead bonding region so as to erode the leads and the signal traces, thereby causing short circuit or signal disconnection and display abnormality in the display device.

### SUMMARY OF THE INVENTION

The present invention is directed to a display device, whereby a hydrophobic protective layer has a surface microstructure for preventing a trace at the underneath from subjecting to external factors and causing abnormities, and thereby provides the display device with favorable structural reliability.

The display device of the present invention includes a first substrate, at least one trace, a hydrophobic protective layer, a flexible printed circuit board, a second substrate and a sealant. The first substrate has a display region and a peripheral region located around the display region. The peripheral region has an outer lead bonding portion connected to the display region. The trace is disposed on the first substrate and extends from the display region into the outer lead bonding portion of the peripheral region. The hydrophobic protective layer is disposed on the first substrate and extends from the display region into the outer lead bonding portion of the peripheral region. The hydrophobic protective layer covers the trace and has at least one opening and a surface microstructure. The opening exposes a portion of the trace to define at least one lead. The lead and the surface microstructure are located in the outer lead bonding portion, and the surface microstructure is located on a surface of the hydrophobic protective layer away from the trace. The flexible printed circuit board is disposed on the first substrate and located in the outer lead bonding portion of the peripheral region. An end of the flexible printed circuit board leans against the surface microstructure of the hydrophobic protective layer, and the flexible printed circuit board is electrically connected to the lead. The second substrate is disposed above the first substrate and overlaps the display region and a portion of the peripheral region of the first substrate. The sealant is disposed between the first substrate and the second substrate, and is located at a boundary between the display region and the peripheral region.

In an embodiment of the present invention, the display device further includes an anisotropic conductive adhesive layer disposed on the first substrate and located between the flexible printed circuit board and the lead, wherein the flexible printed circuit board is electrically connected to the lead through the anisotropic conductive adhesive layer.

In an embodiment of the present invention, the surface microstructure is composed of a plurality of protrusions, and a particle size of each of the protrusions is between 5 microns to 15 microns.

In an embodiment of the present invention, a material of the hydrophobic protective layer is a hydrophobic insulation material.

In an embodiment of the present invention, the display device further includes a surface coating layer disposed on the surface microstructure of the hydrophobic protective layer, wherein the surface coating layer is conformal at the surface microstructure.

In an embodiment of the present invention, a material of the surface coating layer is different from a material of the hydrophobic protective layer.

In an embodiment of the present invention, the material of the surface coating layer is fluoride.

In an embodiment of the present invention, the display device further includes a protective glue at least disposed at a boundary between the surface microstructure of the hydrophobic protective layer and the flexible printed circuit board.

In an embodiment of the present invention, an orthographic projection of the surface microstructure on the first substrate does not overlap an orthographic projection of the lead on the first substrate.

In view of the foregoing, since the display device of the present invention has the hydrophobic protective layer covering the trace, the hydrophobic protective layer has the surface microstructure thereon, and the end of the flexible printed circuit board leans against the surface microstructure of the hydrophobic protective layer, when a user uses a cleaning liquid to clean the display device, the cleaning liquid is unable to be accumulated on the surface microstructure and is also unable to infiltrate through a seam (a joint between the flexible printed circuit board and the surface microstructure), thereby preventing the cleaning liquid from infiltrating the trace and the lead, and thus the normal display of the display device may be maintained and a service life and a structural reliability of the display device may be enhanced.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view schematically illustrating a display device according to an embodiment of the present invention.

FIG. 1B schematically illustrates a cross-sectional view of FIG. 1A along a profile line I-I.

FIG. 2 is a cross-sectional view schematically illustrating a display device according to an embodiment of the present invention.

FIG. 3 is a cross-sectional view schematically illustrating a display device according to another embodiment of the present invention.

FIG. 4A to FIG. 4B are top views schematically illustrating several display devices according to several embodiment of the present invention, respectively.

### DESCRIPTION OF THE EMBODIMENTS

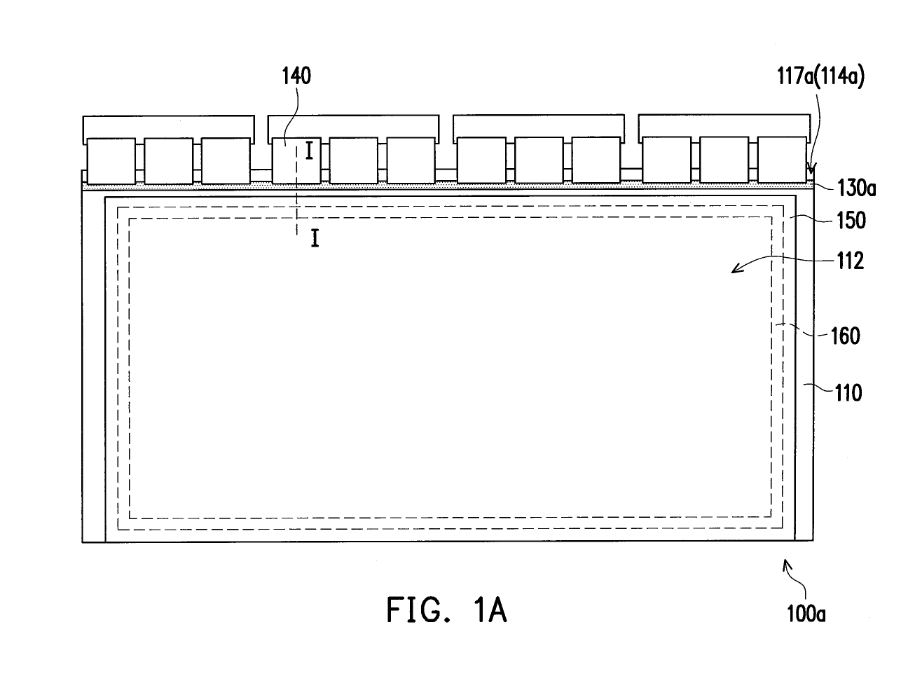

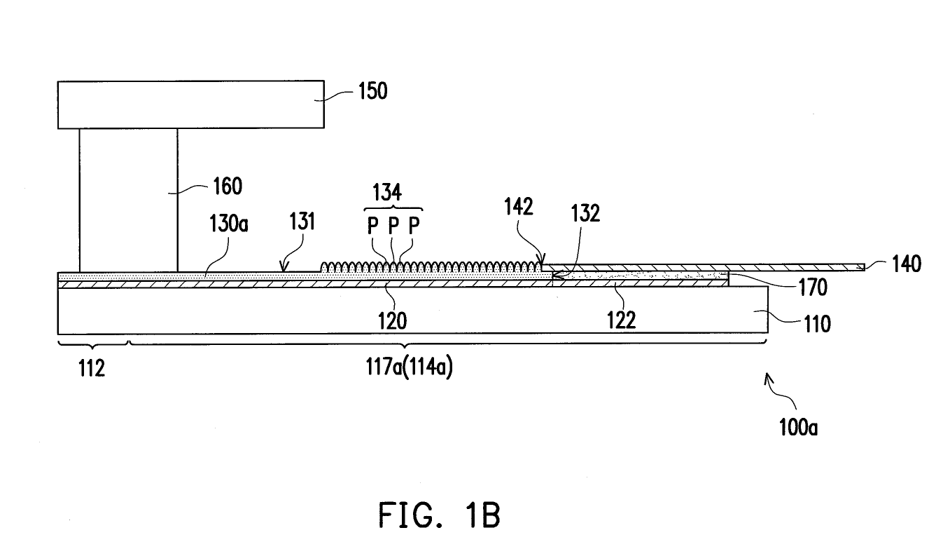

FIG. 1A is a top view schematically illustrating a display device according to an embodiment of the present invention. FIG. 1B schematically illustrates a cross-sectional view of FIG. 1A along a profile line I-I. Referring to FIG. 1A and FIG. 1B together, in the present embodiment, a display device 100a includes a first substrate 110, at least one trace 120, a hydrophobic protective layer 130a, a flexible printed circuit board 140, a second substrate 150 and a sealant 160. In detail, the first substrate 110 has a display region 112 and a peripheral region 114a located around the display region 112. The peripheral region 114a has an outer lead bonding portion 117a connected to the display region 112. The trace 120 is disposed on the first substrate 110 and extends from the display region 112 into the outer lead bonding portion 117a of the peripheral region 114a. The hydrophobic protective layer 130a is disposed on the first substrate 110 and extends from the display region 112 into the outer lead bonding portion 117a of the peripheral region 114a.

Furthermore, the hydrophobic protective layer 130a covers the trace 120 and has at least one opening 132 and a surface microstructure 134, wherein the opening 132 exposes a portion of the trace 120 to define at least one lead 122. The lead 122 and the surface microstructure 134 are located in the outer lead bonding portion 117a. The flexible printed circuit board 140 is disposed on the first substrate 110 and located in the outer lead bonding portion 117a of the peripheral region 114a, wherein an end 142 of the flexible printed circuit board 140 leans against the surface microstructure 134 of the hydrophobic protective layer 130a, and the flexible printed circuit board 140 is electrically connected to the lead 122. The second substrate 150 is disposed above the first substrate 110 and overlaps the display region 112 and a portion of the peripheral region 114a of the first substrate 110. The sealant 160 is disposed between the first substrate 110 and the second substrate 150, and located at a boundary between the display region 112 and the peripheral region 114a.

More specifically, the display device 100a of the present embodiment is, for example, described as being a device that integrates a driving circuit (not shown) into a gate driver on array (GOA) structure, but not limited thereto. In other embodiments, the display device 100a may also be a device that integrates a non-driving circuit (not shown) into a NON-GOA structure or a bilateral drivable structure. The first substrate 110 of the present embodiment is, for example, an active element array substrate, but not limited thereto. The trace 120 is, for example, a first metal layer (for instance, in a same layer as a gate (not shown) of the active element (not shown)) or a second metal layer (for instance, in a same layer as a source (not shown) and a drain (not shown) of the active element (not shown)), but not limited thereto. The second substrate 150 is, for example, a color filter substrate but not limited thereto.

As shown in FIG. 1B, the surface microstructure 134 of the present embodiment is composed of a plurality of protrusions P, wherein a particle size of each of the protrusions P is, favorably, between 5 microns and 15 microns. It is to be noted that, the protrusions P of the present embodiment may be evenly arranged or unevenly arranged on a surface 131 of the hydrophobic protective layer 130a located at the outer lead bonding portion 117a, so that the surface 131 of the hydrophobic protective layer 130a at the outer lead bonding portion 117a is an uneven surface. Herein, an orthographic projection of the surface microstructure 134 on the first substrate 110 does not overlap an orthographic projection of the lead 122 on the first substrate 110. namely, the surface microstructure 134 only covers on the trace 120, but not on the lead 122. It is to be noted that, the surface microstructure 134 may partially cover or completely cover on the surface 131 of the outer lead bonding portion 117a (not including the surface occupied by the sealant 160), but the invention is not limited thereto. Furthermore, a material of the hydrophobic protective layer 130a of the present embodiment is a hydrophobic insulation material, wherein the hydrophobic insulation material may use silicon nitride (SiNx) to perform a surface modification.

In addition, the display device 100a of the present embodiment further includes an anisotropic conductive adhesive layer 170, wherein the anisotropic conductive adhesive layer 170 is disposed on the first substrate 110 and located between the flexible printed circuit board 140 and the lead 122, and the flexible printed circuit board 140 is electrically connected to the lead 122 through the anisotropic conductive adhesive layer 170. As shown in FIG. 1A and FIG. 1B, the outer lead bonding portion 117a of the present embodiment is substantially located on a side of the peripheral region 114a, and thus the hydrophobic protective layer 130a and the flexible printed circuit board 140 are only disposed on a side of the peripheral region 114a.

Since the present embodiment adopts an insulating material having hydrophobic characteristics as the hydrophobic protective layer 130a, when a subsequent user uses the cleaning liquid (not shown) to clean the display device, the cleaning liquid will only remain on the surface 131 of the hydrophobic protective layer 130a (viz., with a contact angle greater than 90°) instead of wetting the surface 131. On the other hand, in the present embodiment, a surface microstructure 134 is further disposed at a seam between the hydrophobic protective layer 130a and the flexible printed circuit board 140, so that a portion of the surface 131 of the hydrophobic protective layer 130a is more rough, thereby enlarging the contact angle (such as greater than 140°) of the cleaning liquid on the surface microstructure 134, and thus the cleaning liquid is hardly able to remain on the surface microstructure 134. As a result, the cleaning liquid is unable to be accumulated on the surface microstructure 134 and is also unable to infiltrate from the seam (a joint between the flexible printed circuit board 140 and the surface microstructure 134), thereby preventing the cleaning liquid from infiltrating the trace 120 and the lead 122, and thus the normal display of the display device 100a may be maintained and a service life and a structural reliability of the display device 100a may be enhanced.

It is to be noted that, the following embodiments have adopted the reference numerals and part of the contents from the previous embodiment, wherein the same reference numerals refer to the same or similar elements, and descriptions of the same technical contents are omitted. The descriptions regarding the omitted part may be referred to the previous embodiment, and thus is not repeated herein.

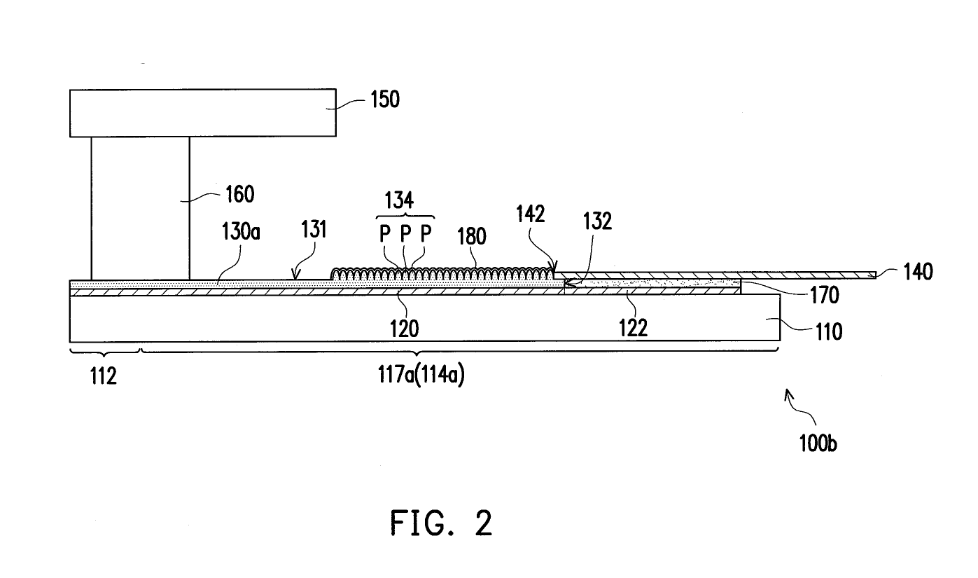

FIG. 2 is a cross-sectional view schematically illustrating a display device according to an embodiment of the present invention. Referring to FIG. 1B and FIG. 2 at the same time, a display device 100b of the present embodiment is similar to the display device 100a of FIG. 1B, except that a main difference between the two lies in: display device 100b of the present embodiment further includes a surface coating layer 180, wherein the surface coating layer 180 is disposed on the surface microstructure 134 of the hydrophobic protective layer 130a, and the surface coating layer 180 is used for the surface microstructure 134 and has an uneven surface. Here, a material of the surface coating layer 180 of the present embodiment is different from the material of the hydrophobic protective layer 130a, wherein the material of the surface coating layer 180 is, for example, fluoride, and may effectively increase a contact angle between the cleaning liquid (not shown) and the surface coating layer 180, so that the cleaning liquid is unable to be accumulated on the surface coating layer 180.

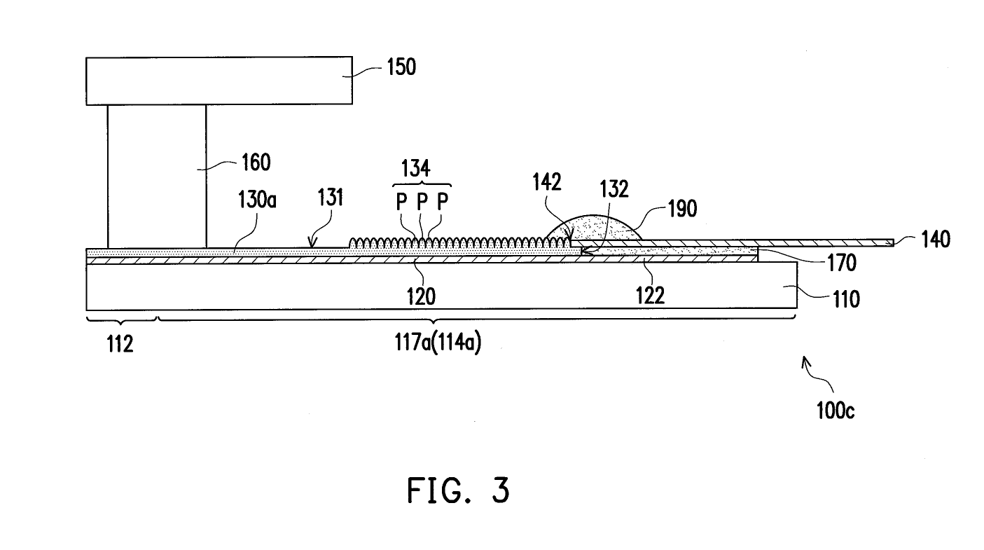

FIG. 3 is a cross-sectional view schematically illustrating a display device according to another embodiment of the present invention. Referring to FIG. 1B and FIG. 3 at the same time, a display device 100c of the present embodiment is similar to the display device 100a of FIG. 1B, except that a main difference between the two lies in: the display device 100c of the present embodiment further includes a protective glue 190, wherein the protective glue 190 is at least disposed at the boundary between the surface microstructure 134 and the hydrophobic protective layer 130a and the flexible printed circuit board 140, thereby may further prevent the cleaning liquid (not shown) from infiltrating the trace 120 and the lead 122.

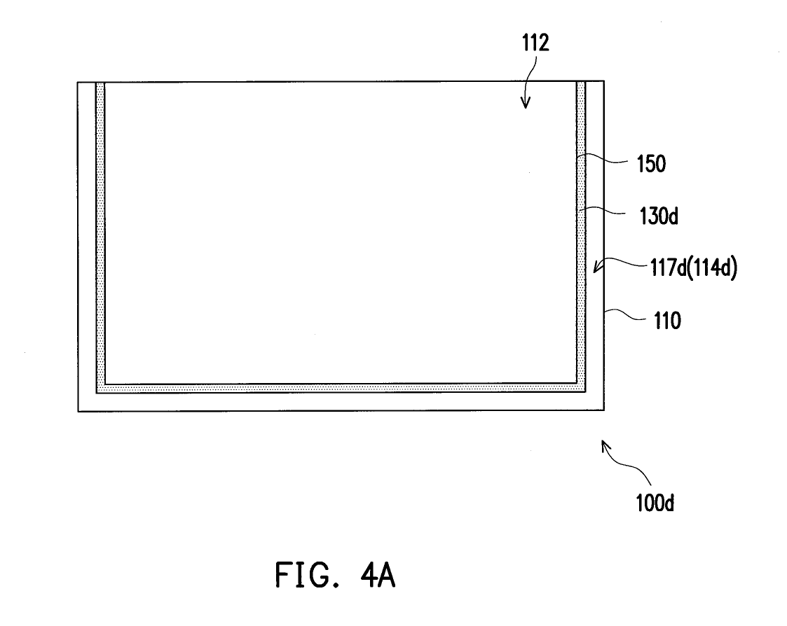

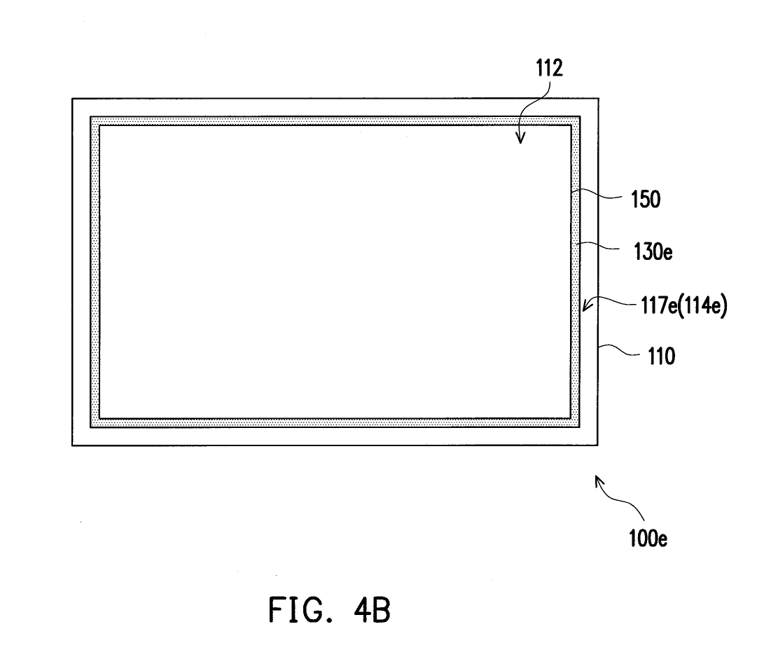

In addition, the present embodiment does not intend to limit the configuration of the hydrophobic protective layer 130a. FIG. 4A to FIG. 4B are top views schematically illustrating several display devices according to several embodiment of the present invention, respectively. For the simplicity of illustration, some elements are omitted in FIG. 4A and FIG. 4B. Referring to FIG. 1A and FIG. 4A together, a display device 100d of the present embodiment is similar to the display device 100a of FIG. 1A, except that a main difference between the two lies in: an outer lead bonding portion 117d of the display device 100d of the present embodiment completely surrounds a peripheral region 114d and exposes a side of the display region 112. That is, a hydrophobic protective layer 130d also completely surrounds the peripheral region 114d and only exposes a side of the display region 112.

On the other hand, referring to FIG. 1A and FIG. 4B together, a display device 100e of the present embodiment is similar to the display device 100a of FIG. 1A, except that a main difference between the two lies in: an outer lead bonding portion 117e of the display device 100e of the present embodiment completely surrounds a peripheral region 114e. That is, a hydrophobic protective layer 130e is also completely surrounds the peripheral region 114e.

In summary, the display device of the present invention has the hydrophobic protective layer covering the trace, the hydrophobic protective layer has the surface microstructure thereon, and an end of the flexible printed circuit board leans against the surface microstructure of the hydrophobic protective layer, and thus when the user use the cleaning liquid to clean the display device, the cleaning liquid is unable to be accumulated on the surface microstructure and is also unable to infiltrate from the seam (the joint between the flexible printed circuit board and the surface microstructure), thereby preventing the cleaning liquid from infiltrating the trace and the lead, and thus the normal display of the display device may be maintained and the service life and the structural reliability of the display device may be enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A display device, comprising:
a first substrate having a display region and a peripheral region located around the display region, the peripheral region having an outer lead bonding portion connected to the display region;
at least one trace disposed on the first substrate and extending from the display region into the outer lead bonding portion of the peripheral region;
a hydrophobic protective layer disposed on the first substrate and extending from the display region into the outer lead bonding portion of the peripheral region, the hydrophobic protective layer covering the trace and having at least one opening and a surface microstructure, the opening exposing a portion of the trace to define at least one lead, the lead and the surface microstructure being located in the outer lead bonding portion, and the surface microstructure being located on a surface of the hydrophobic protective layer away from the trace;
a flexible printed circuit board disposed on the first substrate and located in the outer lead bonding portion of the peripheral region, wherein an end of the flexible printed circuit board leans against the surface microstructure of the hydrophobic protective layer, and the flexible printed circuit board is electrically connected to the lead;
a second substrate disposed above the first substrate and overlapping the display region and a portion of the peripheral region of the first substrate; and
a sealant disposed between the first substrate and second substrate, and located at a boundary between the display region and the peripheral region.

2. The display device as recited in claim 1, further comprising:
an anisotropic conductive adhesive layer disposed on the first substrate and located between the flexible printed circuit board and the lead, wherein the flexible printed circuit board is electrically connected to the lead through the anisotropic conductive adhesive layer.

3. The display device as recited in claim 1, wherein the surface microstructure is composed of a plurality of protrusions, and a particle size of each of the protrusions is between 5 microns to 15 microns.

4. The display device as recited in claim 1, wherein a material of the hydrophobic protective layer is a hydrophobic insulation material.

5. The display device as recited in claim 1, further comprising:
a surface coating layer disposed on the surface microstructure of the hydrophobic protective layer, wherein the surface coating layer is conformal at the surface microstructure.

6. The display device as recited in claim 5, wherein a material of the surface coating layer is different from a material of the hydrophobic protective layer.

7. The display device as recited in claim 6, wherein the material of the surface coating layer is fluoride.

8. The display device as recited in claim 1, further comprising:
a protective glue at least disposed at a boundary between the surface microstructure of the hydrophobic protective layer and the flexible printed circuit board.

9. The display device as recited in claim 1, wherein an orthographic projection of the surface microstructure on the first substrate does not overlap an orthographic projection of the lead on the first substrate.
